(19) United States
(12) Patent Application Publication
(10) Pub. No.: US 2026/0235648 A1
(43) Pub. Date: Aug. 13, 2026

(54) CURRENT SENSOR

(71) Applicant: Alps Alpine Co., Ltd., Tokyo (JP)

(72) Inventors: Manabu TAMURA, Miyagi-ken (JP); Takahiro MAGOME, Miyagi-ken (JP); Minoru ABE, Miyagi-ken (JP); Kazuyoshi WAKABAYASHI, Miyagi-ken (JP)

(21) Appl. No.: 19/639,977

(22) Filed: Apr. 6, 2026

Related U.S. Application Data
(63) Continuation of application No. PCT/JP2024/035986, filed on Oct. 8, 2024.

(30) Foreign Application Priority Data
Nov. 17, 2023 (JP) 2023-196050

(51) Int. Cl. G01R 15/20

(52) U.S. Cl. CPC G01R 15/207

(57) ABSTRACT

A current sensor according to the present invention having high measurement accuracy in which deterioration in measurement accuracy due to positional displacement is suppressed includes a magnetic detection unit, a case, a cover, and a bus bar, wherein the bus bar includes a plate-like portion having a facing surface facing the magnetic detection unit, wherein the plate-like portion is clamped between the case and the cover, wherein the case has a first reference surface, the cover has a second reference surface, and the bus bar has a third reference surface, wherein the case, the cover, and the bus bar are positioned by pressing the first reference surface and the second reference surface against the third reference surface, and wherein the third reference surface is an end face of the plate-like portion of the bus bar in the plate thickness direction.

### CLAIM OF PRIORITY

This application is a Continuation of International Application No. PCT/JP2024/035986 filed on October 8, 2024, which claims benefit of Japanese Patent Application No. 2023-196050 filed on November 17, 2023. The entire contents of each application noted above are hereby incorporated by reference.

### BACKGROUND OF THE INVENTION

### 1. Field of the Invention

The present invention relates to a current sensor configured to measure a current to be measured flowing through a bus bar.

### 2. Description of the Related Art

In recent years, a current sensor configured to measure a current to be measured flowing through devices has been used in order to control a power system of a vehicle or the like provided with various devices. Examples include a coreless current sensor in which a bus bar is insert-molded in a case, and a current sensor using a bus bar that is not insert-molded in a case for the purpose of meeting a demand for cost reduction in the market. In a current sensor, a structure in which a bus bar is not insert-molded in a case, and the case and the bus bar are integrated by assembly makes it possible to accommodate bus bars having various shapes.

Japanese Unexamined Patent Application Publication No. 2010-243440 discloses an assembly structure of a current detection apparatus configured to have a simple configuration, to be easy to assemble, and to be suitable for downsizing the current detection apparatus, in which a protrusion formed on a cover passes through a hole formed in a bus bar and is fitted into a hole formed in a lower surface of a housing.

Japanese Unexamined Patent Application Publication No. 2015-31647 discloses a current sensor configured to provide high accuracy, in which a holder is fixed to a current bar by fastening a magnetic sensor element to the holder with a screw.

Japanese Unexamined Patent Application Publication No. 2019-105613 discloses a current sensor configured to suppress positional displacement between a bus bar and a magnetic detection element, the current sensor including first and second housings configured to sandwich a bus bar and a circuit board, wherein the first and second housings have slide guide portions that are slidable relative to each other in a direction inclined with respect to the thickness direction of the bus bar while being in contact with each other in the thickness direction of the bus bar. In the current sensor, the bus bar is positioned relative to the housing by fitting a protrusion of the first housing into a notch formed in the bus bar.

Japanese Unexamined Patent Application Publication No. 2021-152515 discloses a current sensor configured to provide highly accurate current measurement while reducing restrictions on the shape of a bus bar and reducing deterioration in accuracy due to the relative positional displacement among a magnetic body, the bus bar, and a magnetosensitive element, the current sensor being configured such that a magnetosensitive element mounting portion, a magnetic body mounting portion, and the bus bar are positioned and fixed from the thickness direction of the magnetic body mounting portion. In the current sensor, the bus bar is positioned in the width direction based on a wall of the magnetic body mounting portion.

In the current detection apparatus disclosed in Japanese Unexamined Patent Application Publication No. 2010-243440 and the current sensor disclosed in Japanese Unexamined Patent Application Publication No. 2015-31647, the bus bar is assembled to a case with reference to a screw fastening hole formed in the bus bar, rather than a sensing portion. For this reason, the accuracy of the current sensor may deteriorate due to variations in the characteristics of the bus bar assembled to the case.

In each of the current sensors disclosed in Japanese Unexamined Patent Application Publication No. 2019-105613 and No. 2021-152515, only one of a plurality of separable cases is directly positioned relative to the bus bar, and the other case is positioned with reference to the one case. For this reason, the accuracy of the current sensor may deteriorate due to positional displacement occurring when one case is positioned relative to the other case.

### SUMMARY OF THE INVENTION

The present invention provides a current sensor having high measurement accuracy in which deterioration in measurement accuracy due to positional displacement is suppressed. The present invention has the following configuration to solve the above-described problems.

A current sensor includes a magnetic detection unit, a case, a cover, and a bus bar, wherein the bus bar includes a plate-like portion extending, among an X direction, a Y direction, and a Z direction perpendicular to one another, in the X direction, having a normal direction in the Z direction, and having a facing surface facing the magnetic detection unit, wherein the plate-like portion of the bus bar having the facing surface is clamped between the case and the cover from opposite sides in the Z direction, wherein the case has a first reference surface, the cover has a second reference surface, and the bus bar has a third reference surface, wherein the case, the cover, and the bus bar are positioned by pressing the first reference surface and the second reference surface against the third reference surface, and wherein the third reference surface is an end face of the plate-like portion of the bus bar in the Y direction.

Since both the case and the cover are positioned by pressing the first reference surface and the second reference surface against the third reference surface of the bus bar, positional displacement due to variations in dimensions and assembly can be suppressed. Furthermore, by using, as the third reference surface for positioning, an end face in the Y direction of the plate-like portion having a facing surface facing the magnetic detection unit, the positional relationship among the case, the cover, and the bus bar in the Y direction can be accurately defined in the vicinity of a sensing portion to be detected by the magnetic detection unit. Accordingly, a current sensor having high measurement accuracy can be provided.

The bus bar may include a constricted portion having a cutout portion recessed in the Y direction, and the third reference surface may be the one end face of the constricted portion in the Y direction.

The case may include a bus-bar groove in a surface facing the cover, the bus bar being placeable in the bus bar groove, wherein the bus-bar groove may include a guide portion projecting in the Y direction as viewed along the Z direction, and wherein the guide portion may be inserted in the cutout portion and may have the first reference surface at a portion facing the third reference surface.

The cover may include a pillar portion projecting in the Z direction from a surface facing the case, wherein the guide portion and the pillar portion may be inserted into and fitted in the cutout portion, and wherein the pillar portion may have the second reference surface at a portion facing the third reference surface.

A pair of guide portions may be provided apart from each other in the X direction with a gap therebetween, wherein the pillar portion may be fitted in the gap, and wherein the two guide portions forming a pair in the X direction and the pillar portion may be fitted in the cutout portion.

A structure in which the two guide portions and the pillar portion positioned in the gap therebetween are fitted into the cutout portion of the bus bar allows looseness in the X-Y plane to be suppressed with the busbar assembled within the case.

The bus bar may include a pair of cutout portions on both sides of the plate-like portion in the Y direction, wherein the case may include a pair of guide portions in the X direction, the guide portions corresponding to the pair of cutout portions, wherein the cover may include a pair of pillar portions corresponding to the pair of cutout portions, and wherein the end face of the constricted portion in the one cutout portion may be the third reference surface, the guide portions fitted in the one cutout portion may each have the first reference surface, and the pillar portion fitted in a gap between the pair of guide portions in the X direction and fitted in the one cutout portion may have the second reference surface.

With this configuration, the case and the cover can be positioned with reference to the bus bar. By bringing the surfaces into contact with each other, looseness in the direction of rotation along the X-Y plane can be suppressed.

The other end face of the constricted portion opposite to the one end face having the third reference surface may be a pressing surface, wherein the guide portions facing the pressing surface may each have a first protrusion projecting in the Y direction in a surface facing the pressing surface, wherein the pillar portion may have a second protrusion projecting in the Y direction in a surface facing the pressing surface, and wherein the first protrusion and the second protrusion may press against the pressing surface.

By providing the first protrusion and the second protrusion projecting in the Y direction, the pressing surface provided on the other end face opposite to one end face of the constricted portion having the third reference surface can be pressed. Accordingly, the first reference surface of the guide portion and the second reference surface of the pillar portion can be firmly brought into contact with the third reference surface of the one end face of the constricted portion, thereby enabling reliable positioning.

The cutout portion may have X-facing surfaces facing each other in the X direction, wherein, of a pair of guide portions arranged in the X direction, one guide portion may have a third protrusion projecting in the X direction on a surface facing one of the X-facing surfaces, wherein a surface of the other of the guide portions facing the other of the X-facing surfaces and the other of the X-facing surfaces of the cutout portion may be in contact with each other, and wherein the third protrusion may press against the other of the X-facing surfaces.

By pressing the third protrusion of the one guide portion against one X-facing surface of the cutout portion, a surface of the other guide portion facing the X-facing surface and the other X-facing surface of the cutout portion can be brought into contact with each other via the pillar portion of the cover. This allows positions of the case and the cover with respect to the busbar in the X direction to be accurately aligned and determined based on the busbar.

The current sensor may have a U-shaped magnetic shield member, wherein the magnetic shield member may be insert-molded in the cover, and both end portions thereof may project from a surface of the cover facing the bus bar, wherein a pair of pillar portions may be each disposed between the end portions of the magnetic shield member so as to be in contact with the magnetic shield member, and wherein, as viewed from the case side toward the cover along the Z axis, the magnetic detection unit may be disposed between the end portions of the magnetic shield member.

Since the U-shaped magnetic shield member reduces external magnetic noise, the measurement accuracy of the current sensor is improved. By disposing the pair of pillar portions inside the magnetic shield member, an outer dimension of the current sensor can be reduced. This also suppresses deterioration of linearity of measurement of the current sensor due to tilting (warpage/deformation) of the magnetic shield member.

The case may have shield holes into which the end portions of the magnetic shield member are insertable without coming into contact with the guide portions. With the configuration in which the distal ends of the magnetic shield member do not come into contact with the guide portions, the magnetic shield member does not interfere during positioning of the case, the cover, and the bus bar, thereby improving workability.

A dimension of the magnetic shield member in the Y direction may be smaller than a dimension of the bus bar in the Y direction, and the magnetic shield member may be disposed so as not to extend beyond the bus bar in the Y direction. By setting the dimension of the magnetic shield member smaller than the width of the bus bar, a current sensor that is reduced in size in the width direction, is less susceptible to the influence of an external magnetic field, and has high noise immunity can be provided.

The current sensor may include a pair of holding members configured to integrally hold the case, the cover, and the bus bar, wherein the bus bar may include a pair of through-holes through which the holding members are insertable, and wherein the pair of through-holes may be respectively disposed on opposite sides of the constricted portion in the X direction with the constricted portion interposed therebetween. The holding members may be screws.

With the above configuration, the case, the cover, and the bus bar can be integrally held by the pair of holding members such as screws.

The magnetic detection unit may be mounted on a case-facing surface of the substrate, wherein the substrate may be provided above the substrate-facing surface of the case opposite to a bus-bar-facing surface facing the bus bar, wherein the substrate may include the cutout portions, wherein the case may include engaging portions projecting from the substrate-facing surface, and wherein by engaging the cutout portions with the engaging portions, the substrate may be positioned with respect to the case.

The cover may include second through-holes through which the screws are insertable, wherein the case may include screw-hole bosses projecting in the Z direction from the substrate-facing surface, wherein the substrate may be positioned between the two screw-hole bosses in the X direction as viewed along the Z direction, and wherein the substrate may be provided closer to the substrate-facing surface of the case than to a straight line connecting distal end portions of the two screw-hole bosses as viewed along the Y direction.

The two screw-hole bosses can protect the substrate therebetween and ensure an insulation distance between an external member and the substrate, thereby enabling the current sensor to have a lower profile.

The case may include a wall portion projecting from the substrate-facing surface in the Z direction so as to surround the periphery of the substrate, wherein the wall portion may project from the substrate-facing surface to at least a position corresponding to a surface of the substrate opposite to the case-facing surface.

By surrounding the periphery of the substrate with the wall portion extending from the substrate-facing surface to a position higher than the substrate, the substrate is protected, and an impact caused when the case contacts an external member is less likely to be directly applied to the substrate, thereby preventing damage to the substrate and improving the reliability of the current sensor.

The cover may include, on a bottom surface opposite to the bus-bar-facing surface facing the bus bar, a protruding portion and a bottom portion that is a region other than the protruding portion, wherein a portion of the magnetic shield member may be insert-molded within the protruding portion, wherein second through-holes through which the screws are insertable may be provided in the bottom portion of the bottom surface, and wherein a height from the bottom portion to a distal end of the protruding portion in the Z direction may be greater than a height from the bottom portion to screw heads of the screws inserted through the second through-holes.

By providing a protruding portion in which a part of the magnetic shield member is insert-molded, the protruding portion being higher than the heads of the screws, interference between the screw heads and another member can be prevented.

The cover may include partition wall portions projecting from the bottom portion in the Z direction and extending in the X direction. The partition wall portions may be disposed on opposite sides of each of the second through-holes in the Y direction. By providing the partition wall portions in addition to the protruding portion, stability of the current sensor when the cover is placed with the protruding portion facing downward can be improved. Furthermore, since contact between the screw heads and other members can be prevented, the insulation performance of the screws can be improved.

A height of the partition wall portions from the bottom portion and a height of the protruding portion from the bottom portion of the bottom surface in the Z direction may be equal to each other. This configuration eliminates a level difference between the partition wall portions and the protruding portion, thereby improving stability of the current sensor when the cover is placed with the protruding portion facing downward.

The current sensor may further include three fixing portions configured to fix the substrate to the case. With the three fixing portions, positional displacement between the cover and the substrate can be suppressed, whereby deterioration in the measurement accuracy of the current sensor caused by positional displacement therebetween can also be suppressed.

As viewed from the Z direction, a right triangle may be formed by three straight lines connecting the fixing portions, wherein an opposite side and an adjacent side of the right triangle intersecting at a right angle may each be parallel to the X direction or the Y direction, and wherein a hypotenuse facing the right angle of the right triangle may overlap a part of the magnetic detection unit.

One of protruding portions of the bus bar projecting from opposite sides of the case may include a bent portion, and two of the three fixing portions may be provided in a region closer to the bent portion than to a center of the substrate in the X direction.

When the bus bar is fastened, a portion of the case near the bent portion tends to be deformed. For this reason, two fixing portions are provided in a region near the protruding portion having the bent portion. This increases the force for firmly fixing the substrate to the case in a portion where deformation is likely to occur. Accordingly, even when the case is deformed during fastening of the bus bar, the substrate can remain fixed to the case.

A current sensor includes a magnetic detection unit, a case, and a cover, wherein the case has a first reference surface configured to perform positioning by being pressed against an end face of the bus bar in a width direction thereof, and wherein the cover has a second reference surface configured to perform positioning by being pressed against the end face of the bus bar in the width direction thereof.

The present invention can suppress deterioration in detection accuracy of a current sensor due to positional displacement by using a bus bar as a reference in positioning a case and a cover. Accordingly, it is possible to provide a current sensor having high measurement accuracy in which deterioration in measurement accuracy due to positional displacement is suppressed.

### BRIEF DESCRIPTION OF THE DRAWINGS

FIG. 1 is a perspective view illustrating the external appearance of a current sensor according to an embodiment of the present invention;

FIG. 2 is a perspective view illustrating a state in which a case and a substrate are removed from the current sensor in FIG. 1;

FIG. 3 is a partial cross-sectional view of the current sensor taken along line III-III in FIG. 1, in which a vicinity of a surface of a bus bar is cut along the X-Y plane;

FIG. 4 is a partial cross-sectional view of the current sensor taken along line IV-IV in FIG. 1, in which a vicinity of a surface of the bus bar is cut along the X-Y plane;

FIG. 5 is a perspective view of a cover and a magnetic shield member of the current sensor;

FIG. 6 is a perspective view of the case of the current sensor;

FIG. 7 is a plan view illustrating a positional relationship between the bus bar and the magnetic shield member in the current sensor;

FIG. 8 is a cross-sectional view of the current sensor taken along line VIII-VIII in FIG. 1, the current sensor being cut along the X-Z plane;

FIG. 9 is a perspective view illustrating the external appearance of the current sensor as viewed from the case side;

FIG. 10 is a perspective view illustrating the external appearance of the current sensor as viewed from the cover side;

FIG. 11 is a perspective view illustrating the external appearance of a modification of the current sensor; and

FIG. 12 is a partial cross-sectional view of the current sensor in another modification taken at a position corresponding to line XII-XII in FIG. 1, in which a vicinity of a surface of the bus bar is cut along the X-Y plane.

### DESCRIPTION OF THE PREFERRED EMBODIMENTS

Embodiments of the present invention will be described hereinbelow with reference to the accompanying drawings. In the drawings, the same members are denoted by the same reference numerals, and description thereof will be omitted as appropriate. In order to indicate a positional relationship among the members, reference coordinates are shown in the drawings as appropriate. In the reference coordinates, the extending direction of a bus bar is defined as an X direction, the width direction of the bus bar perpendicular to the X direction is defined as a Y direction, and the stacking direction of the bus bar and a magnetic detection unit perpendicular to the X direction and the Y direction is defined as a Z direction. The Y direction is the direction of the sensitivity axis of the magnetic detection unit, and the X direction and the Z direction are perpendicular to the sensitivity axis.

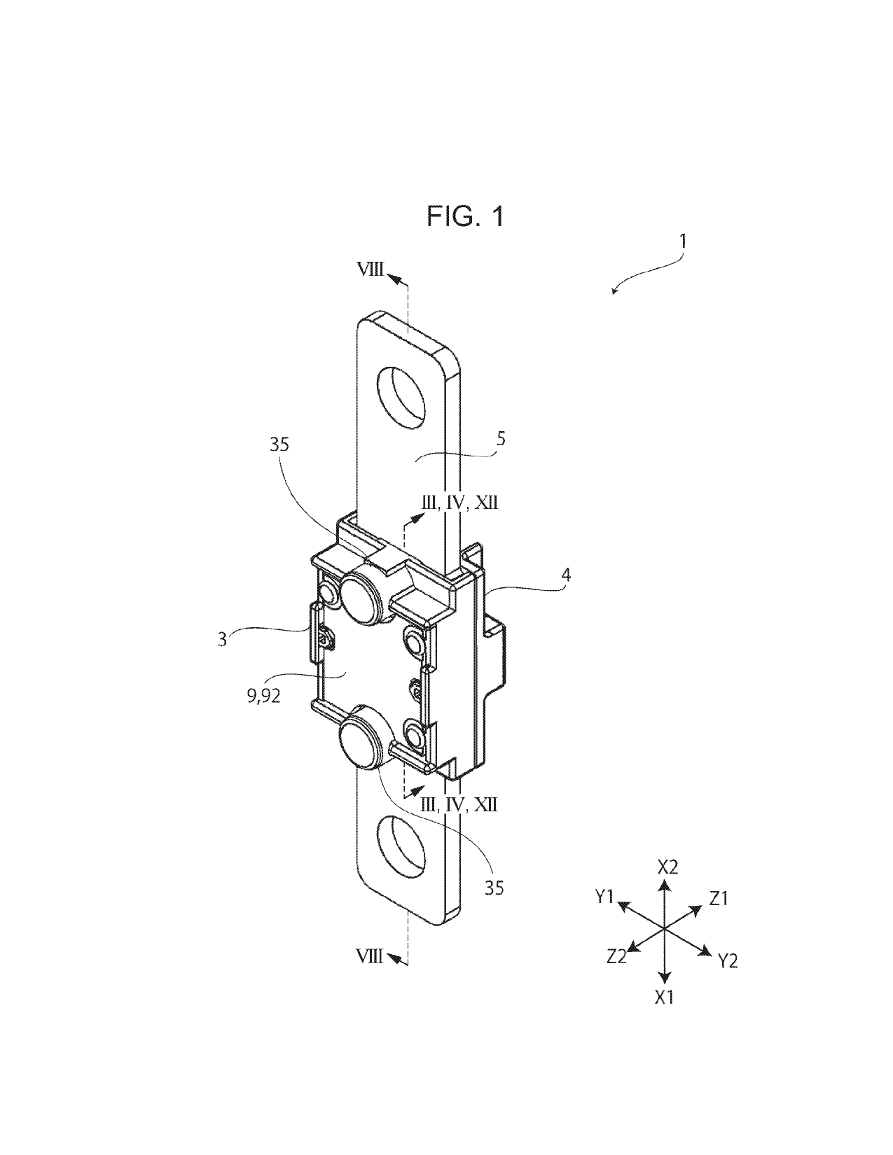

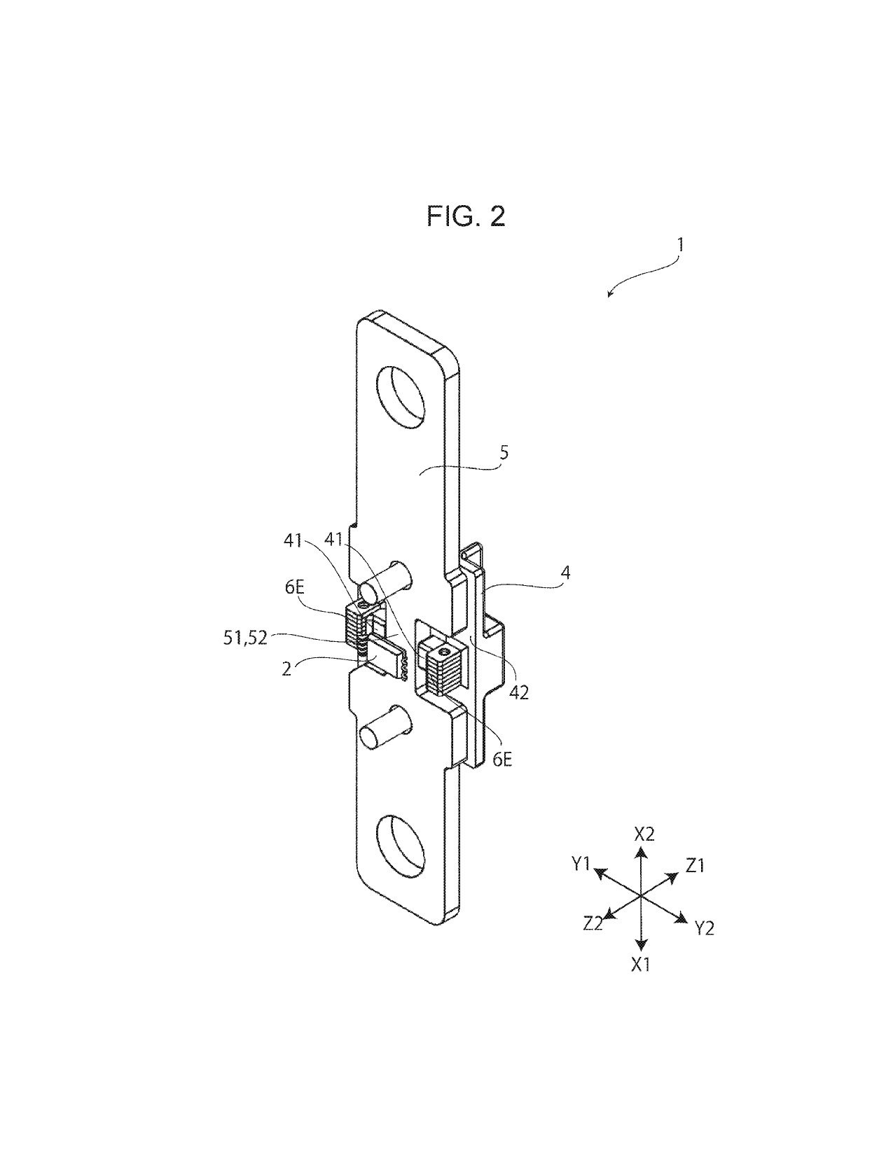

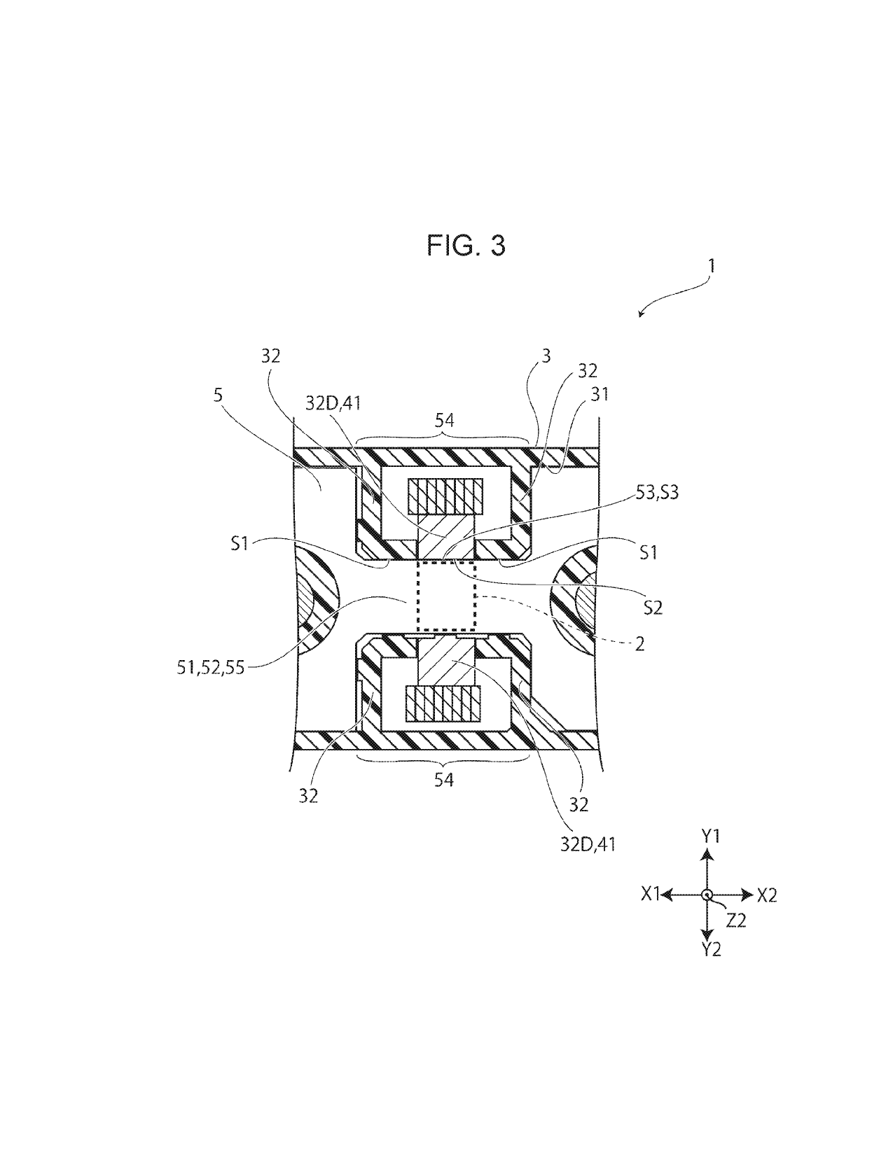

FIG. 1 is a perspective view illustrating the external appearance of a current sensor 1 according to the present embodiment. FIG. 2 is a perspective view illustrating a state in which a case 3 and a substrate 9 are removed from the current sensor 1. FIG. 3 is a partial cross-sectional view of the current sensor 1 taken along line III-III in FIG. 1, in which a vicinity of a surface of a bus bar 5 is cut along the X-Y plane. As illustrated in FIGS. 1 to 3, the current sensor 1 includes a magnetic detection unit 2, the case 3, a cover 4, and the bus bar 5.

The magnetic detection unit 2 is configured to detect magnetism generated by the bus bar 5 when a current to be measured (hereinafter referred to as a "target current") flows through the bus bar 5. The magnetic detection unit 2 is provided on a substrate 9 so as to face the bus bar 5 in the Z direction among the X direction, the Y direction, and the Z direction, which are perpendicular to one another. The sensitivity axis of the magnetic detection unit 2 is the Y direction, and the magnetic detection unit 2 can detect a magnetic field in the Y direction. Since a current flows through the bus bar 5 along the X direction, magnetism generated by the bus bar 5 as an induced magnetic field can be accurately detected by the magnetic detection unit 2 by causing a detection surface of the magnetic detection unit 2 to directly face the bus bar 5.

As a detection element of the magnetic detection unit 2, a magnetoresistive element, a Hall element, or the like may be used. The above configuration illustrates, by way of example, a case in which a magnetoresistive element is used as the detection element, and the magnetic detection unit 2 is disposed such that a detection surface thereof directly faces the bus bar 5. When another detection element is used, it is necessary to dispose the detection element such that the orientation of a detection surface is changed as appropriate.

The bus bar 5 includes a plate-like portion 52 that extends in the X direction, has a normal direction in the Z direction, and has a facing surface 51 facing the magnetic detection unit 2. The bus bar 5 has cutout portions 54 formed in a recessed shape on both sides of the plate-like portion 52 in the Y direction. The cutout portions 54 are formed symmetrically with respect to a center line of the plate-like portion 52 in the Y direction. The bus bar 5 is a plate-shaped conductor through which a target current flows and which is made of, for example, copper, brass, or aluminum. The current sensor 1 holds the plate-like portion 52 having the facing surface 51 of the bus bar 5 by sandwiching the plate-like portion 52 between the case 3 and the cover 4 from both sides in the Z direction.

The case 3 and the cover 4 are made of resin or the like. The case 3 has a first reference surface S1, the cover 4 has a second reference surface S2, and the bus bar 5 has a third reference surface S3. By pressing the first reference surface S1 of the case 3 and the second reference surface S2 of the cover 4 against the third reference surface S3 of the bus bar 5, the case 3, the cover 4, and the bus bar 5 are positioned relative to one another.

As illustrated in FIG. 3, the case 3 and the cover 4 (see FIGS. 1 and 2) are pressed, at the first reference surface S1 and the second reference surface S2, against the third reference surface S3 of the bus bar 5, and are positioned in the Y direction relative to the bus bar 5 using the third reference surface S3. By positioning the case 3 and the cover 4 with reference to the bus bar 5 in this manner, positional displacement in the Y direction that may occur due to variations in dimensions, assembly, or the like can be reduced.

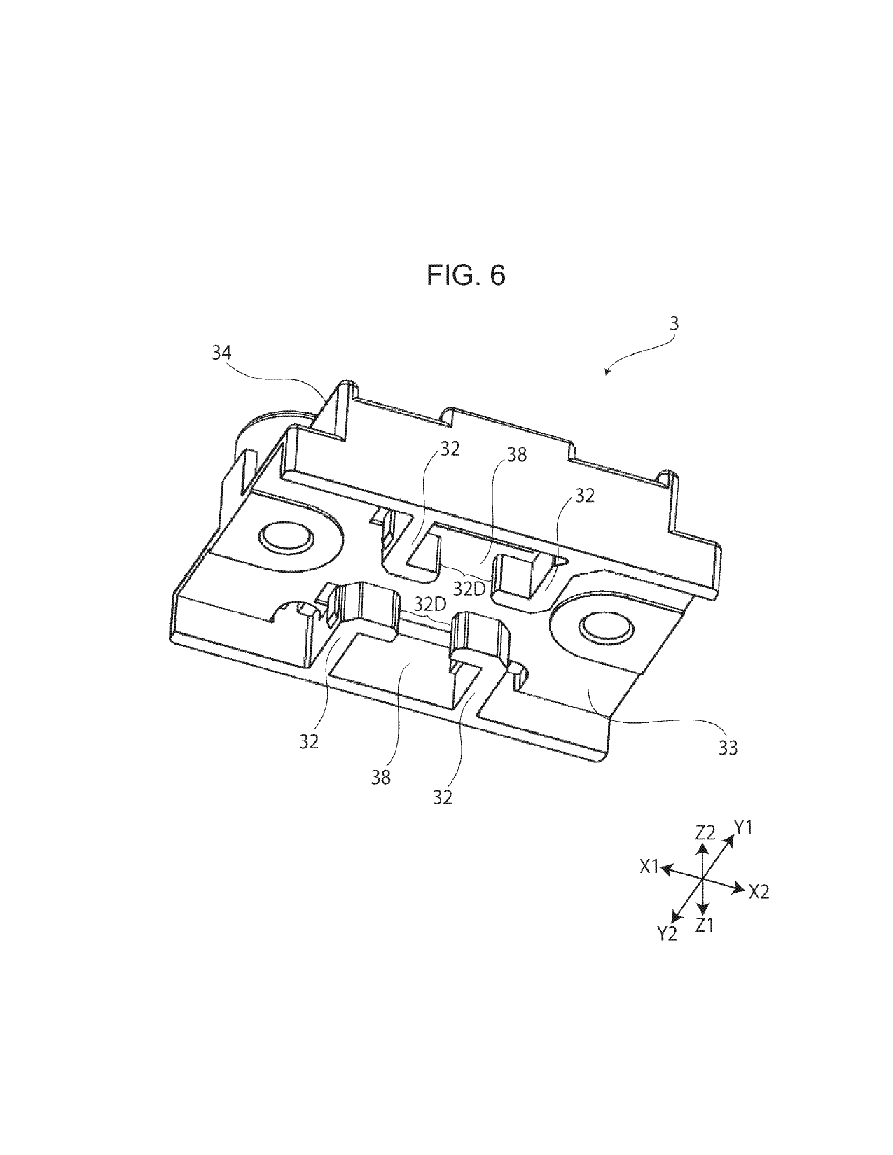

Although details will be described later, the substrate 9 on which the magnetic detection unit 2 is mounted is attached to a surface of the case 3 on the Z2 side (a substrate-facing surface 34; see FIG. 6). As described above, by pressing the first reference surface S1 of the case 3 against the third reference surface S3 of the bus bar 5, a position of the case 3 relative to the bus bar 5 in the Y direction can be accurately determined. Accordingly, positional displacement of the magnetic detection unit 2 relative to the bus bar 5 in the Y direction can be reduced.

Hereinafter, a magnetic field generated when the target current flows through the bus bar 5 will be described. When the generated magnetic field is viewed along the X direction, an elliptical magnetic field having a major axis extending along the Y direction is formed around the bus bar 5. For this reason, as a distance from a center position of the bus bar 5 in the Y direction increases in the Y1 direction or the Y2 direction, a Y-direction component of the magnetic field that can be detected by the magnetic detection unit 2 decreases, and a Z-direction component thereof increases.

In other words, when positional displacement in the Y direction occurs between the bus bar 5 and the magnetic detection unit 2, measurement accuracy of the magnetic detection unit 2 may also be affected.

Accordingly, by positioning the case 3 and the cover 4 with reference to the bus bar 5, variations in measurement accuracy of the magnetic detection unit 2 can also be reduced.

The current sensor 1 uses, as the third reference surface S3, an end face 53 in the Y direction (a plate-thickness surface) of the plate-like portion 52 of the bus bar 5 having the facing surface 51 facing the magnetic detection unit 2. In other words, the end face 53 of each cutout portion 54 on the Y1 side in the Y direction functions as the third reference surface S3 used as a positioning reference. As described above, by using the plate-like portion 52 located in the vicinity of the magnetic detection unit 2 as a positioning reference, a positional relationship among the case 3, the cover 4, and the bus bar 5 in the Y direction can be accurately defined. Accordingly, deterioration in detection accuracy of the current sensor 1 due to deviation from a predetermined position can be suppressed.

FIG. 3 illustrates a case in which both contact between the first reference surface S1 and the third reference surface S3, and contact between the second reference surface S2 and the third reference surface S3 are surface contact. However, the configuration of positioning is not limited to surface contact. For example, at least one of the two contacts described above may be point contact or line contact. In this case, one or both of the two contacting portions may be a line, a point, or a surface.

The bus bar 5 illustrated in FIG. 3 has a constricted portion 55 serving as a narrow-width portion in which the cutout portions 54 recessed in the Y direction are formed on both sides in the Y direction and a wide-width portion in which no cutout portion 54 is formed. By providing the constricted portion 55, which has a width narrower than that of the wide-width portion provided on both sides in the X direction, between the wide-width portions, the influence of the skin effect at high frequencies can be suppressed at the constricted portion 55. For this reason, by measuring a magnetic field generated at the constricted portion 55 using the magnetic detection unit 2, a current sensor 1 having high measurement accuracy can be obtained.

The case 3 may include, on a Z1-side surface facing the cover 4, a bus-bar groove 31 in which the bus bar 5 can be disposed. The bus-bar groove 31 may include guide portions 32 that project in the Y direction as viewed along the Z direction. When the bus bar 5 is disposed in the bus-bar groove 31, the guide portions 32 may be inserted into the cutout portions 54. Each guide portion 32 may have the first reference surface S1 at a portion that faces the third reference surface S3 when inserted into the cutout portion 54.

In the case 3 illustrated in FIG. 3, as viewed along the Z direction, the guide portions 32 project in the Y direction from both sides of the bus-bar groove 31 in the Y direction so as to face each other toward the constricted portion 55 of the bus bar 5.

The cover 4 may include pillar portions 41 projecting toward the Z2 side in the Z direction from a bus-bar-facing surface 42 (see FIG. 2) facing the bus bar 5.

The guide portions 32 of the case 3 and the pillar portions 41 of the cover 4 may be inserted into respective cutout portions 54 of the bus bar 5. In other words, as viewed along the Z direction, the guide portions 32 and the pillar portions 41 may be provided at positions overlapping respective cutout portions 54 of the bus bar 5.

Each pillar portion 41 may have the second reference surface S2 at a portion facing the third reference surface S3 of the bus bar 5 when inserted into the cutout portion 54.

As viewed along the Z direction, a pair of guide portions 32 may be provided apart from each other in the X direction at a position overlapping one of the cutout portions 54. Between the two guide portions 32, a gap 32D into which each pillar portion 41 can be fitted is formed. When the case 3 and the cover 4 are engaged, the pillar portion 41 may be inserted into and fitted in the gap 32D. In other words, when the bus bar 5 is sandwiched between the case 3 and the cover 4, two guide portions 32 arranged as a pair in the X direction and the pillar portion 41 fitted in the gap 32D function together and may be fitted into the cutout portion 54 of the bus bar 5. With this configuration, by incorporating the bus bar 5 into the case 3 and the cover 4, looseness in the X-Y plane can be suppressed.

The bus bar 5 may include cutout portions 54 on both sides of the plate-like portion 52 in the Y direction. The case 3 may include two guide portions 32 arranged as a pair in the X direction and corresponding to the two cutout portions 54. The cover 4 may include two pillar portions 41 corresponding to the two cutout portions 54. In FIG. 3, the end face 53 of the constricted portion 55 in one of the cutout portions 54 on the Y1 side of the bus bar 5 is the third reference surface S3. A guide portion 32 fitted in one of the cutout portions 54 may have the first reference surface S1, and a pillar portion 41 fitted in the gap 32D between the two guide portions 32 arranged as a pair and fitted in the one cutout portion 54 may have the second reference surface S2.

In this manner, the pillar portion 41 is fitted in the gap 32D between the pair of guide portions 32 in a state in which the first reference surface S1 of the pair of guide portions 32 and the second reference surface S2 of the pillar portion 41 are in contact with the third reference surface S3 of the cutout portion 54. Since the guide portion 32 and the pillar portion 41, which are integrated by fitting, are fitted into the cutout portion 54, positions of the case 3 and the cover 4 relative to the bus bar 5 in the Y direction can be reliably and stably determined.

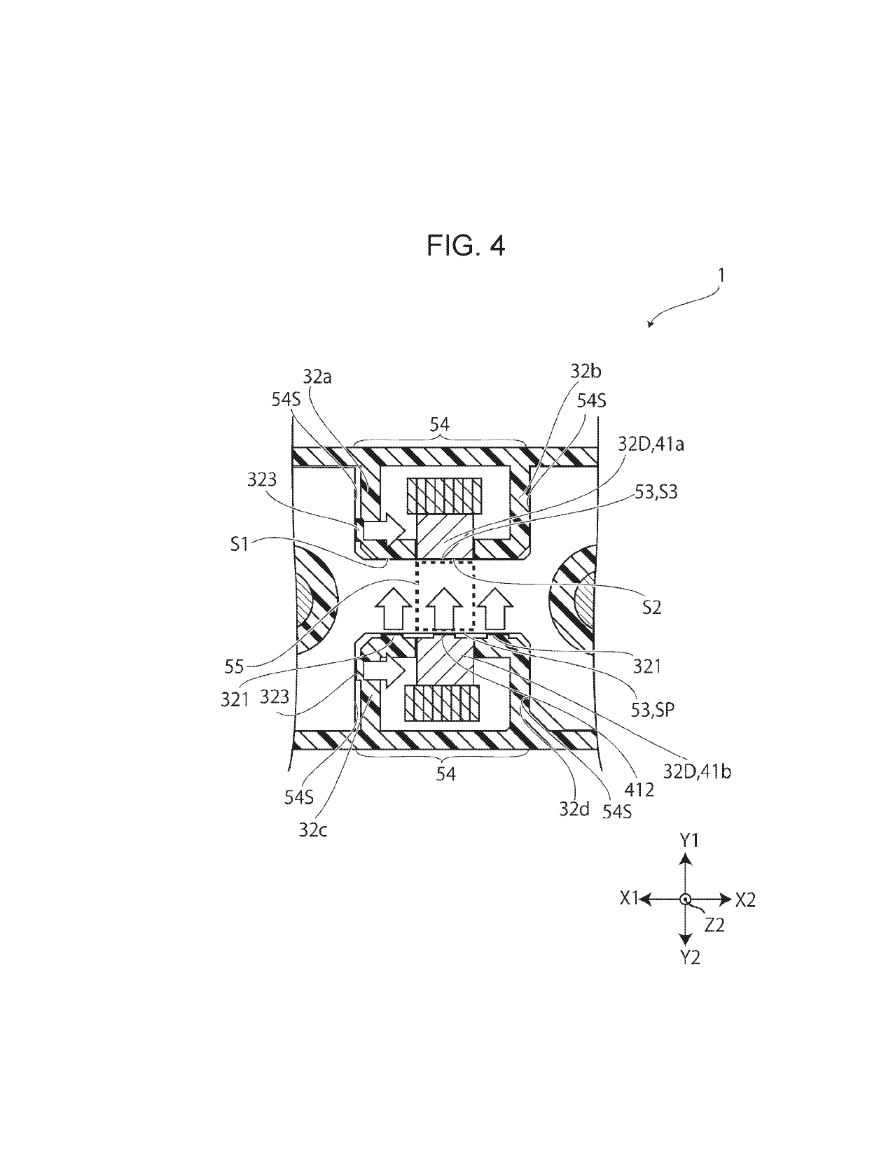

FIG. 4 is a partial cross-sectional view of the current sensor 1 taken along line IV-IV in FIG. 1, in which a vicinity of a surface of the bus bar 5 is cut along the X-Y plane. As illustrated in FIG. 4, the other end face 53 of the constricted portion 55 opposite to the one end face 53 having the third reference surface S3 is a pressing surface SP. Guide portions 32c and 32d facing the pressing surface SP may each have, on a surface facing the pressing surface SP, a first protrusion 321 that projects toward the Y1 side in the Y direction.

A pillar portion 41b fitted in the gap 32D between the two guide portions 32c and 32d each having the first protrusion 321 may have, on a surface facing the pressing surface SP, a second protrusion 412 that projects toward the Y1 side in the Y direction.

A distance from Y1-side end portions of the first protrusion 321 and the second protrusion 412 to guide portions 32a and 32b arranged opposite to the first protrusion 321 and the second protrusion 412 in the Y1 direction is set to be equal to or slightly smaller than a dimension of the constricted portion 55 of the bus bar 5 in the Y direction. For this reason, the first protrusion 321 and the second protrusion 412 are brought into pressure contact with the pressing surface SP to urge the bus bar 5 in a direction indicated by hollow arrows (toward the Y1 side in the Y direction) illustrated in FIG. 4. In FIG. 4, a direction in which the bus bar 5 is urged when the first protrusion 321 and the second protrusion 412 are brought into pressure contact with the pressing surface SP is indicated by the hollow arrows.

The first protrusion 321 and the second protrusion 412 may press the pressing surface SP provided on the other end face 53 of the constricted portion 55 of the bus bar 5 toward the Y1 side in the Y direction. This allows the first reference surfaces S1 of the guide portions 32c and 32d and the second reference surface S2 of the pillar portion 41b to be reliably and stably brought into contact with the third reference surface S3 provided on the one end face 53 of the constricted portion 55 on the Y1 side. Accordingly, the case 3 and the cover 4 can be directly positioned in the Y direction with reference to the end face 53 of the constricted portion 55 of the bus bar 5.

The two cutout portions 54 may each have X-facing surfaces 54S facing each other in the X direction. The guide portions 32a and 32b, which form a pair with the gap 32D interposed therebetween, are inserted (disposed) between the opposed X-facing surfaces 54S while being arranged along the X direction. Similarly, the guide portions 32c and 32d, which form a pair with the gap 32D interposed therebetween, are inserted (disposed) between the opposed X-facing surfaces 54S while being arranged along the X direction. The guide portions 32a and 32b form a pair in the X direction, and the guide portions 32c and 32d form a pair in the X direction.

Of the two guide portions 32a and 32b forming a pair, one guide portion 32a may include a third protrusion 323 projecting in the X direction on a surface facing one X-facing surface 54S of the cutout portion 54, and the third protrusion 323 is in pressure contact with the one X-facing surface 54S. A surface of the other guide portion 32b that faces the other X-facing surface 54S of the cutout portion 54 may be in contact with the other X-facing surface 54S.

Similarly, of the two guide portions 32c and 32d forming a pair, one guide portion 32c may include a third protrusion 323, and the other guide portion 32d may be in contact with the other X-facing surface 54S.

Of the two guide portions 32a and 32b forming a pair, the third protrusion 323 of one guide portion 32a may press against one X-facing surface 54S of the cutout portion 54. This allows a surface of the other guide portion 32b facing the other X-facing surface 54S to be reliably brought into surface contact with the other X-facing surface 54S of the cutout portion 54 via the pillar portion 41a of the cover 4.

Similarly, of the two guide portions 32c and 32d, the third protrusion 323 of one guide portion 32c may press against one X-facing surface 54S of the cutout portion 54. This allows a surface of the other guide portion 32d facing the other X-facing surface 54S to be reliably brought into contact with the other X-facing surface 54S of the cutout portion 54 via the pillar portion 41b of the cover 4.

With the above configuration, positions of the case 3 and the cover 4 relative to the bus bar 5 in the X direction can be determined based on the X-facing surface 54S of the bus bar 5. Accordingly, positions of the case 3 and the cover 4 relative to the bus bar 5 in the X direction can be accurately determined.

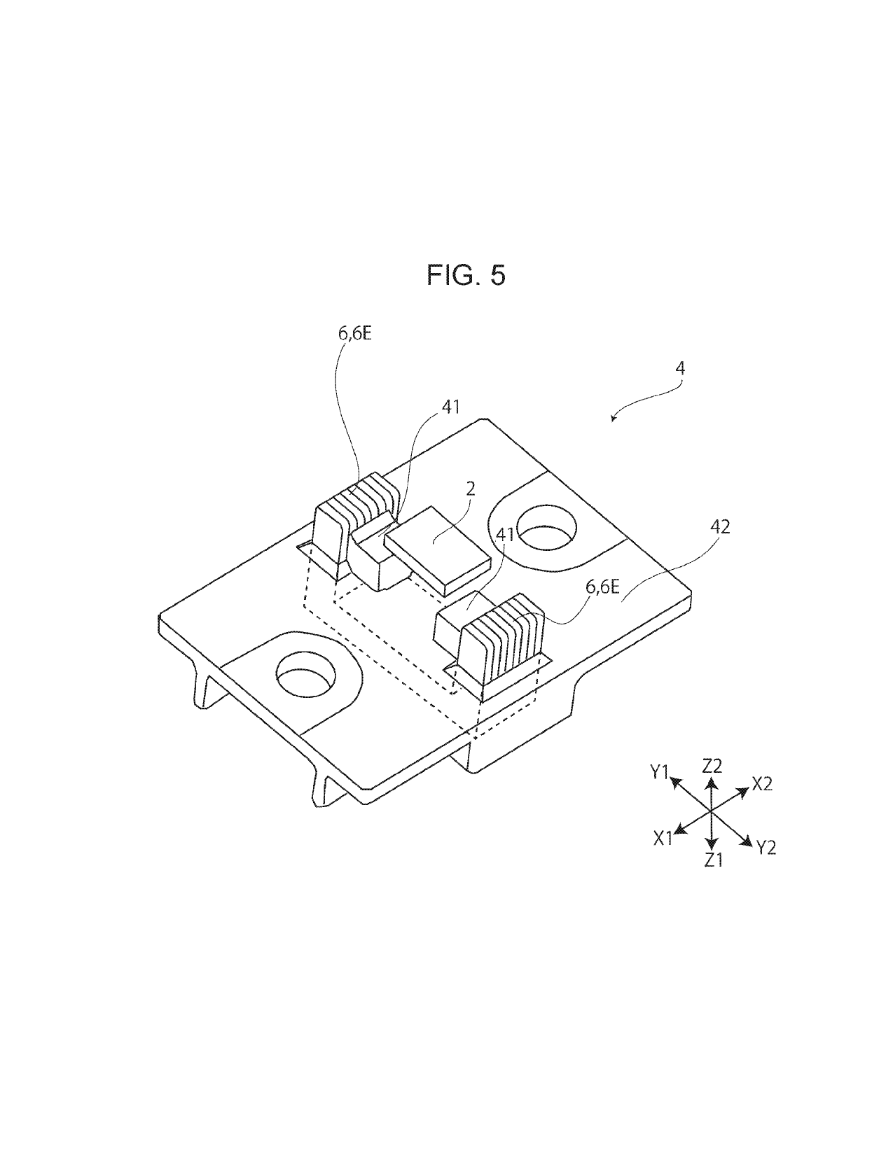

FIG. 5 is a perspective view of the cover 4 and the magnetic shield member 6 of the current sensor 1 (see FIG. 1). As illustrated in FIG. 5, the current sensor 1 may include a U-shaped magnetic shield member 6. At least a part of the magnetic shield member 6 may be insert-molded in the cover 4, and end portions 6E may project from the bus-bar-facing surface 42 of the cover 4 facing the bus bar 5. A pair of pillar portions 41 may each be disposed between the end portions 6E of the magnetic shield member 6 so as to be in contact with the magnetic shield member 6. As viewed from the case 3 side toward the cover 4 along the Z axis, the magnetic detection unit 2 may be disposed between the end portions 6E of the magnetic shield member 6.

As the magnetic shield member 6, for example, a plurality of metal plate members having the same shape and stacked one on another are used. Since the magnetic shield member 6 can suppress magnetic noise affecting the magnetic detection unit 2, the measurement accuracy of the current sensor 1 is improved.

By disposing the pair of pillar portions 41 inside the magnetic shield member 6, that is, between the end portions 6E of the magnetic shield member 6, an outer dimension of the current sensor 1 can be reduced. This also suppresses deterioration of linearity of an output of the current sensor 1 due to tilting (warpage/deformation) of the magnetic shield member 6.

FIG. 6 is a perspective view of the case 3 of the current sensor 1 (see FIG. 1). As illustrated in FIG. 6, the case 3 may include shield holes 38 into which the end portions 6E (see FIG. 5) of the magnetic shield member 6 can be inserted without coming into contact with the guide portions 32. In other words, the case 3 may include the guide portions 32 forming pairs in the X direction (32a and 32b, and 32c and 32d; see FIG. 4). Each guide portion 32 is formed as a wall-like member projecting in the Z direction. On a side of each wall-like member opposite to the bus-bar groove 31, a shield hole 38 is formed, into which an end portion 6E of the magnetic shield member 6 can be inserted without coming into contact with a guide portion 32. The bus-bar groove 31 and the shield hole 38 communicate with each other via the gap 32D.

The case 3 may be provided with shield holes 38, so that, when the bus bar 5 is clamped between the case 3 and the cover 4, the distal end portions 6E of the magnetic shield member 6 do not come into contact with the guide portions 32. For this reason, during positioning of the case 3, the cover 4, and the bus bar 5, the case 3 and the magnetic shield member 6 do not interfere with each other, and such interference does not affect assembly.

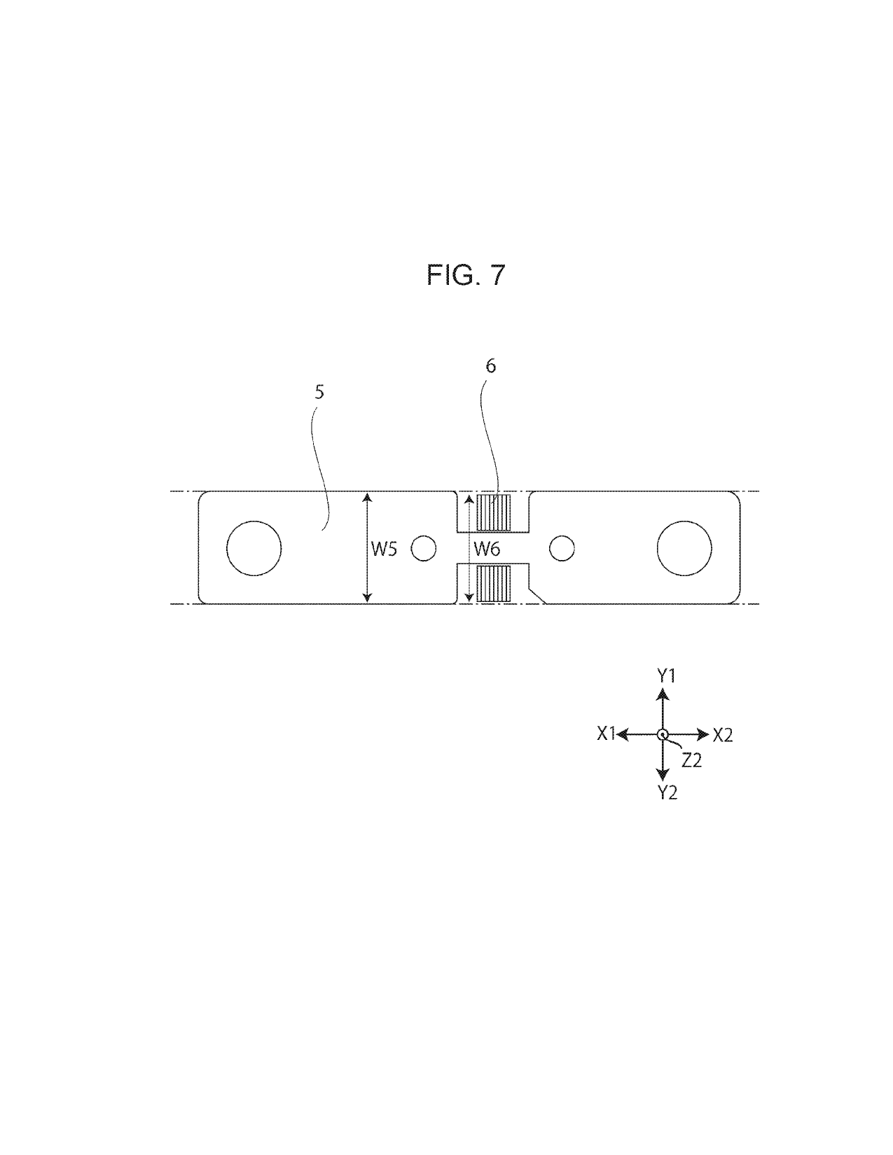

FIG. 7 is a plan view illustrating a positional relationship between the bus bar 5 and the magnetic shield member 6 in the current sensor 1. As illustrated in FIG. 7, a dimension W6 of the magnetic shield member 6 in the Y direction is smaller than a dimension W5 of the bus bar 5 in the Y direction. The magnetic shield member 6 is disposed so as not to extend beyond the bus bar 5 in the Y direction.

With this configuration, the magnetic shield member 6 does not become excessively larger than the width of the bus bar 5, thereby enabling a size reduction in the width direction. Accordingly, it is possible to provide the current sensor 1 that is less susceptible to the influence of an external magnetic field and has high noise immunity.

Here, the dimension in the Y direction refers to the dimension of a portion of each of the bus bar 5 and the magnetic shield member 6 having the largest width in the Y direction. The phrase "the magnetic shield member 6 does not extend beyond the bus bar 5" means that, as viewed along the Z direction, when virtual straight lines extending in the X direction and indicated by chain lines in FIG. 7 are drawn so as to be in contact with portions having the largest width in the Y direction, the entirety of the magnetic shield member 6 is positioned between the virtual straight lines.

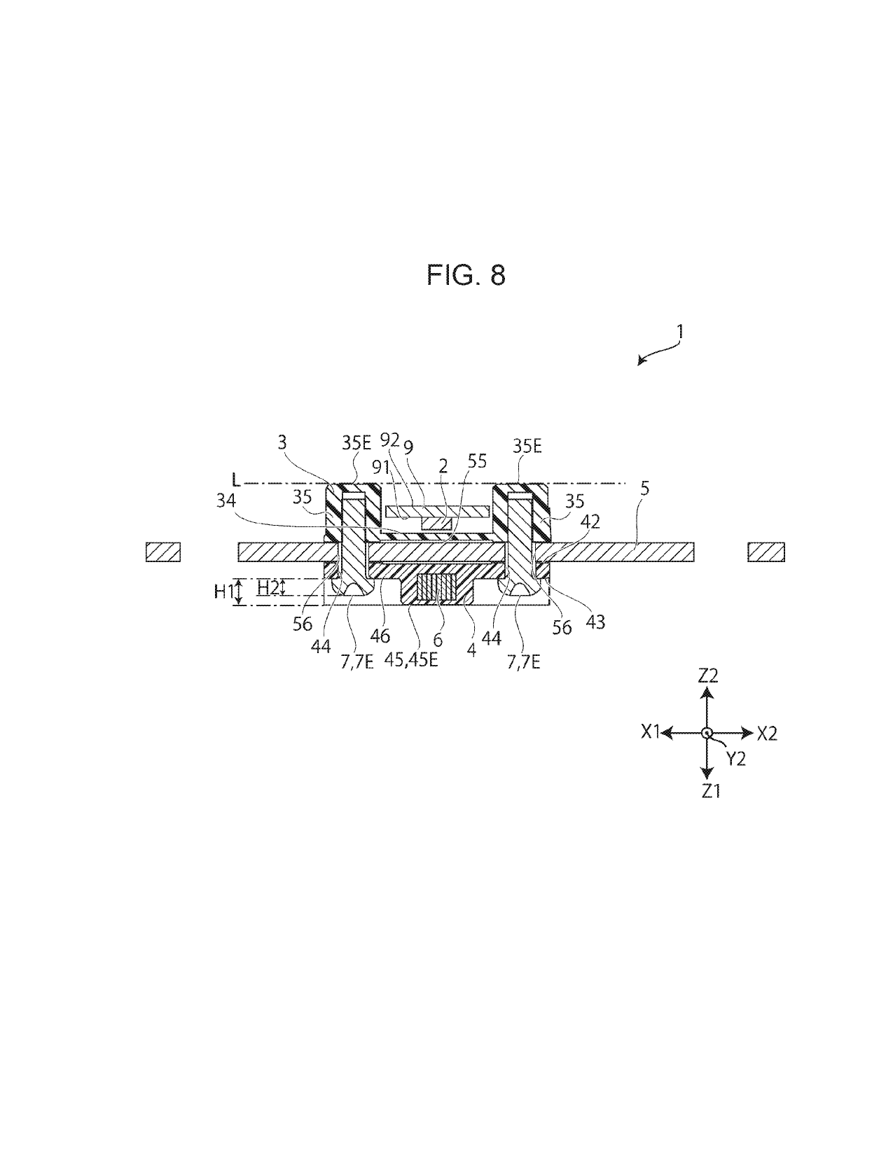

FIG. 8 is a cross-sectional view of the current sensor 1 taken along line VIII-VIII in FIG. 1, the current sensor 1 being cut along the X-Z plane. As illustrated in FIG. 8, the current sensor 1 may include screws 7 as a pair of holding members that integrally hold the case 3, the cover 4, and the bus bar 5. The bus bar 5 may be provided with a pair of through-holes 56 through which the screws 7 can be inserted. The pair of through-holes 56 may be disposed on opposite sides of the constricted portion 55 of the bus bar 5 in the X direction.

The case 3 may include screw-hole bosses 35 projecting in the Z direction from the substrate-facing surface 34 (see FIG. 6) at positions corresponding to the pair of through-holes 56. The cover 4 may be provided with second through-holes 44 through which the screws 7 can be inserted. With the screw-hole bosses 35, the second through-holes 44, and the through-holes 56 aligned, the screws 7 are inserted from the cover 4 side, pass through the second through-holes 44 and the through-holes 56, and are screwed into the screw-hole bosses 35, whereby the case 3, the cover 4, and the bus bar 5 can be integrally held by the screws 7.

As illustrated in FIGS. 8 and 1, as viewed along the Z direction, the substrate 9 may be positioned between the two screw-hole bosses 35 in the X direction. As viewed along the Y direction, the substrate 9 may be provided closer to the substrate-facing surface 34 of the case 3 than to a straight line L connecting distal end portions 35E of the two screw-hole bosses 35.

With the above configuration, the substrate 9 can be protected by the screw-hole bosses 35, and a distance for insulating the substrate 9 from members external to the current sensor 1 can be ensured. In other words, even when an external member is disposed near the substrate 9 on the Z2 side, the X1 side, or the X2 side, and the external member comes into contact with the current sensor 1 due to a malfunction or the like, the risk of the external member coming into direct contact with the substrate 9 can be reduced, and a creepage distance from the substrate 9 to the external member can be increased. This can reduce the likelihood of damage to the substrate 9 or occurrence of a short circuit in wiring provided on the substrate 9. Accordingly, since there is no need to provide a member that covers the entire Z2 side of the substrate 9, the height in the Z direction can be reduced, whereby the height of the current sensor 1 can be made lower in profile.

The cover 4 may include, on a bottom surface 43 opposite to the bus-bar-facing surface 42 facing the bus bar 5, a protruding portion 45 and a bottom portion 46, which is a region other than the protruding portion 45. A portion of the magnetic shield member 6 may be insert-molded within the protruding portion 45. Second through-holes 44 through which the screws 7 can be inserted may be provided in the bottom portion 46 of the bottom surface 43.

A height H1 from the bottom portion 46 to a distal end 45E of the protruding portion 45 in the Z direction may be greater than a height H2 from the bottom portion 46 to a screw head 7E of each screw 7 inserted through the second through-hole 44. Thus, the height H1 by which the protruding portion 45 of the cover 4, in which a portion of the magnetic shield member 6 is insert-molded, projects from the bottom portion 46 is greater than the height H2 by which the screw head 7E of the screw 7 projects from the bottom portion 46. This allows the screw 7 to be protected by the protruding portion 45, thereby preventing the screw head 7E from coming into contact with another member. Even when the case 3, the cover 4, and the bus bar 5 are held by the screws 7, the screw heads 7E do not project beyond the distal ends 45E toward the Z1 side, thereby contributing to a lower profile of the current sensor 1.

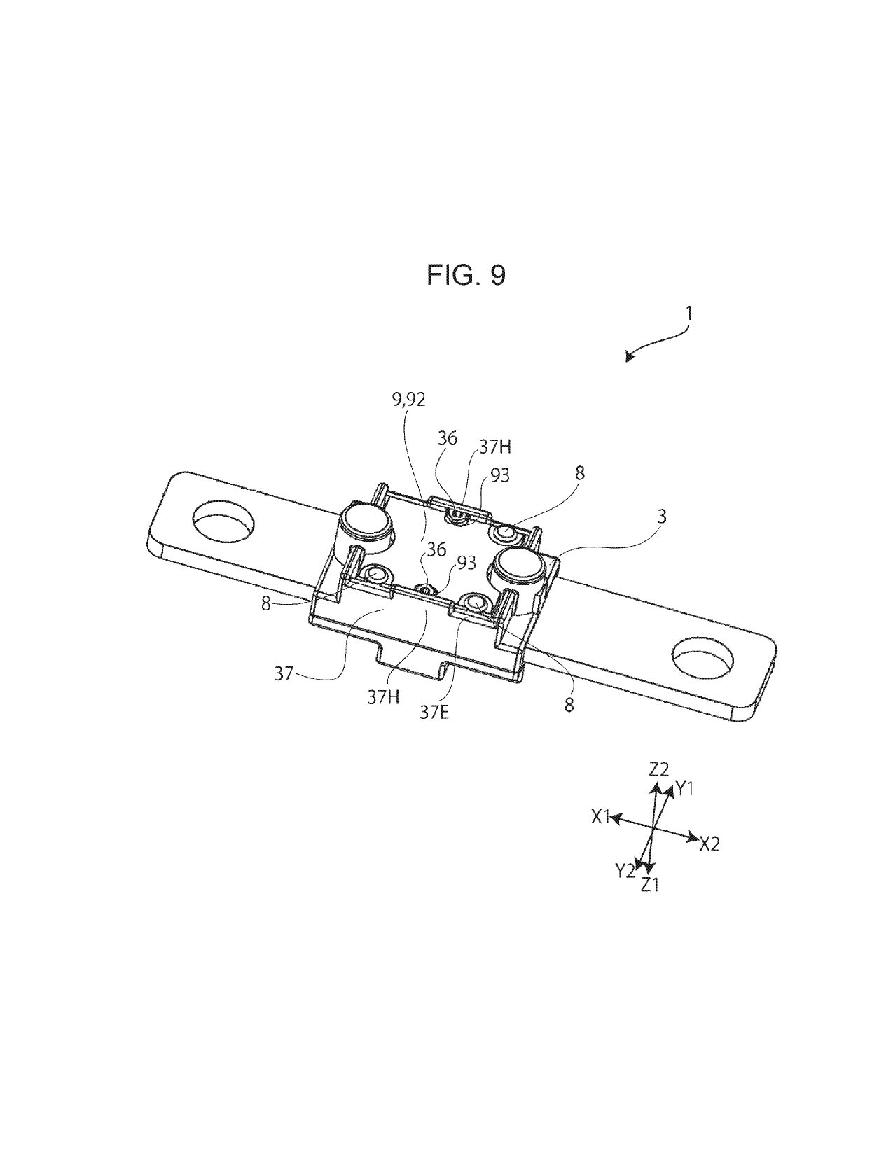

FIG. 9 is a perspective view illustrating the external appearance of the current sensor 1 as viewed from the case 3 side. The substrate 9 includes a case-facing surface 91 facing the case 3 and an outer surface 92 opposite to the case-facing surface 91, and the magnetic detection unit 2 is mounted on the case-facing surface 91 (see FIGS. 8 and 1). The substrate 9 is provided above the substrate-facing surface 34 (see FIG. 6) of the case 3 opposite to the bus-bar-facing surface 33 that faces the bus bar 5. Since the magnetic detection unit 2 is disposed in a space between the substrate 9 and the case 3, the likelihood of an external member or the like directly colliding with the magnetic detection unit 2 is reduced.

As illustrated in FIG. 9, the substrate 9 may include two cutout portions 93. The case 3 may include two engaging portions 36 projecting from the substrate-facing surface 34. By engaging the two cutout portions 93 with the two engaging portions 36, the substrate 9 can be easily positioned with respect to the case 3. Although the number of the cutout portions 93 and the engaging portions 36 may be one or three or more, two is preferable from the viewpoint of ease and accuracy of positioning.

The case 3 may include a wall portion 37 that projects from the substrate-facing surface 34 (see FIG. 6) in the Z direction so as to surround the periphery of the substrate 9. The wall portion 37 may project from the substrate-facing surface 34 to the same position as the outer surface 92 of the substrate 9, which is opposite to the case-facing surface 91. In other words, the wall portion 37 may be provided such that the distance from the substrate-facing surface 34 to a wall end 37E of the wall portion 37 is greater than or equal to the distance from the substrate-facing surface 34 to the outer surface 92 of the substrate 9.

By providing the case 3 with the wall portion 37 that surrounds the periphery of the substrate 9 to protect the substrate 9, the reliability of the current sensor 1 can be improved by, for example, reducing an impact that occurs when the current sensor 1 collides with an external member or preventing damage to the substrate 9.

The distance from the substrate-facing surface 34 to the wall end 37E of the wall portion 37 does not have to be the same over the entire wall portion 37, and a portion having a greater distance to the wall end 37E than other portions may be provided. For example, as illustrated in FIG. 9, a wall portion 37H may be provided in which the distance from the substrate-facing surface 34 to the wall end 37E is greater than in other portions of the wall portion 37, such that the cutout portion 93 and the engaging portion 36 are covered by the wall portion 37H as viewed along the Y direction. By providing the wall portion 37H, the risk of the cutout portion 93 and the engaging portion 36 coming into contact with an external member can be reduced.

The current sensor 1 may include three fixing portions 8 configured to fix the substrate 9 to the case 3. By providing the three fixing portions 8, positional displacement between the case 3 and the substrate 9 can be reliably suppressed. For this reason, deterioration in the measurement accuracy of the current sensor 1 due to such positional displacement can be suppressed. Examples of the configuration of the fixing portion 8 include screw fastening, thermal caulking, metal caulking, press-fitting, and soldering.

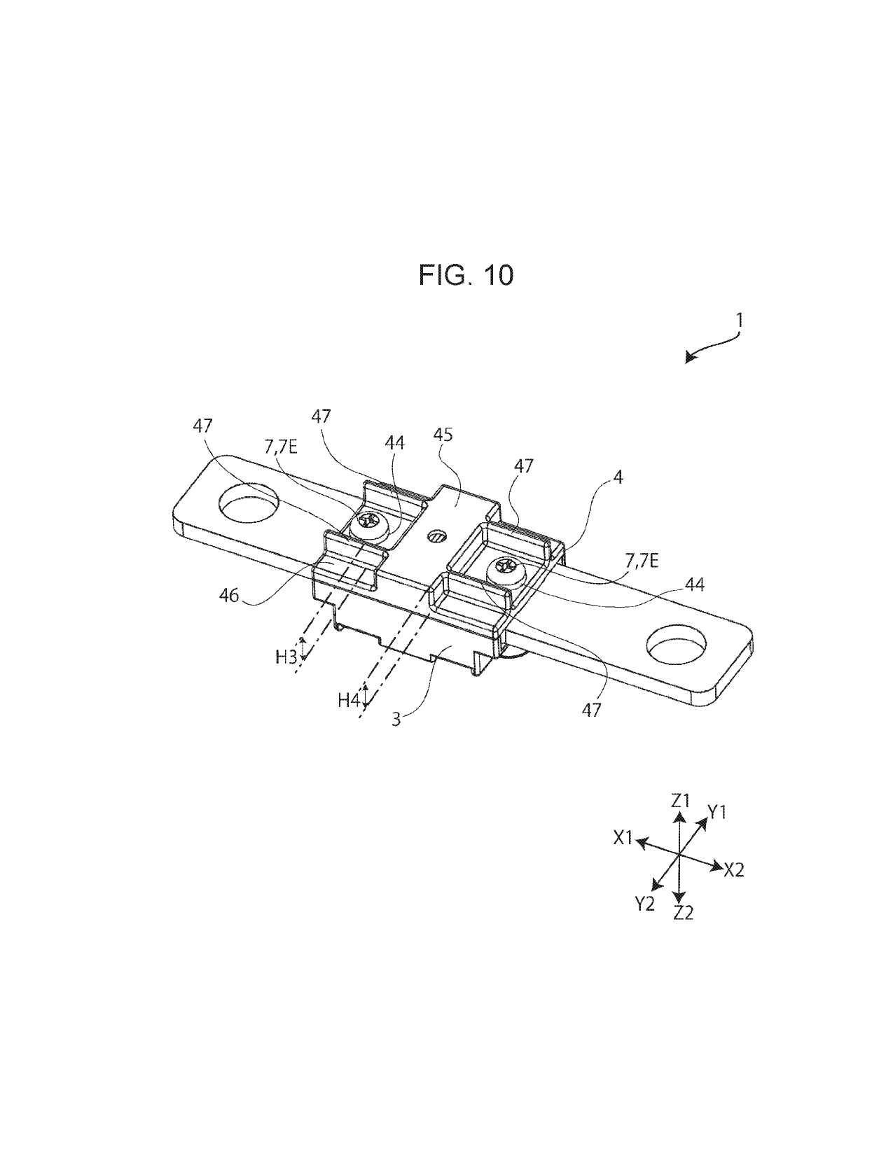

FIG. 10 is a perspective view illustrating the external appearance of the current sensor 1 as viewed from the cover 4 side. As illustrated in FIG. 10, the cover 4 may include partition wall portions 47 projecting from the bottom portion 46 in the Z direction and extending in the X direction. By providing the partition wall portions 47 in addition to the protruding portion 45, stability when the cover 4 of the current sensor 1 is placed with the protruding portion 45 facing downward can be improved. Furthermore, since contact between the screw heads 7E and other members can be prevented, the insulation performance of the screws 7 can be improved.

In the current sensor 1, the partition wall portions 47 may be disposed on opposite sides of each second through-hole 44 in the Y direction. By providing the partition wall portions 47 on opposite sides of the second through-hole 44, the screws 7 can be protected from three sides, thereby preventing contact between the screw heads 7E and other members.

In the cover 4, the height H3 of the partition wall portion 47 from the bottom portion 46 and the height H4 of the protruding portion 45 from the bottom portion 46 in the Z direction may be equal to each other. This configuration eliminates a level difference between the partition wall portion 47 and the protruding portion 45, thereby improving stability when the cover 4 of the current sensor 1 is placed with the protruding portion 45 facing downward.

### Modifications

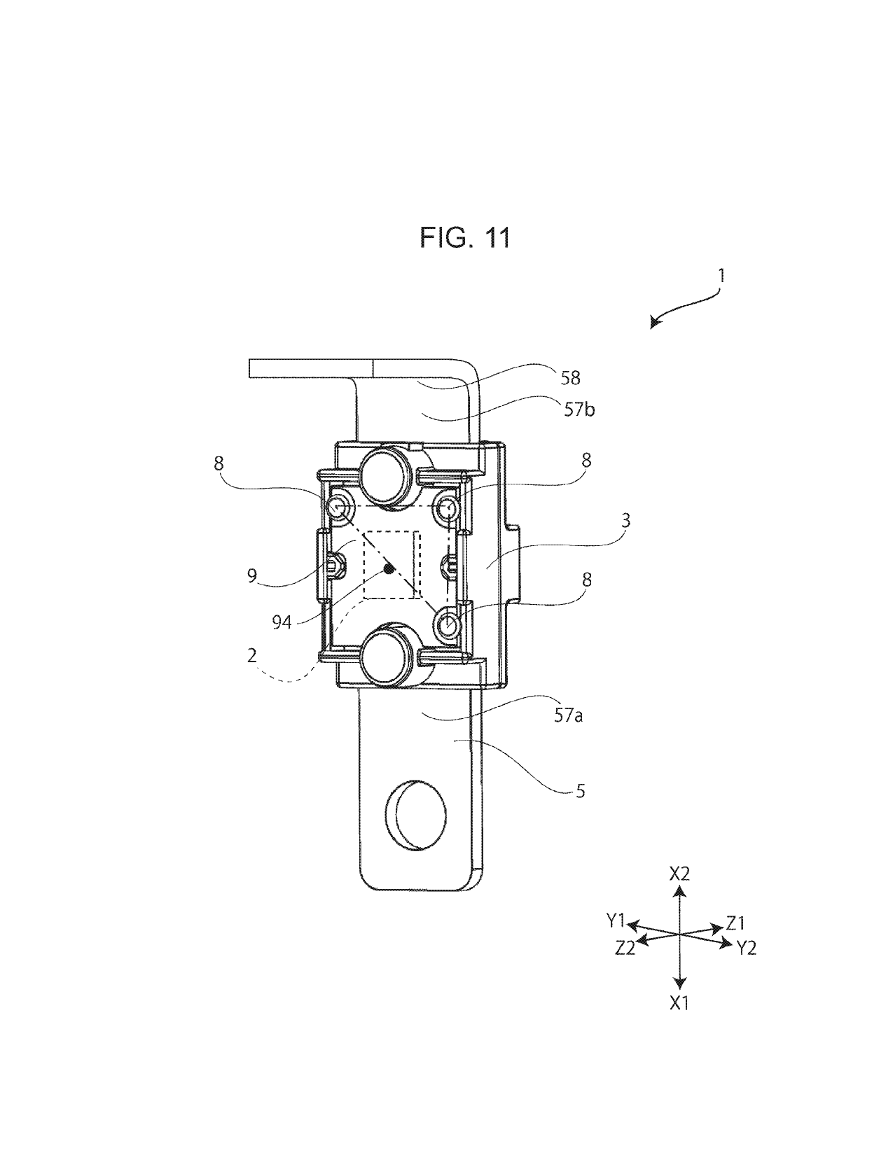

FIG. 11 is a perspective view illustrating the external appearance of a modification of the current sensor 1. In FIG. 11, the position of the magnetic detection unit 2 provided on the substrate 9 is indicated by a broken line.

As indicated by a chain line in FIG. 11, the current sensor 1 may include the fixing portions 8 at positions where a right triangle is formed by three straight lines connecting the fixing portions 8 as viewed from the Z direction. In the right triangle, the opposite side and the adjacent side that intersect at a right angle may each be parallel to the X direction or the Y direction, and the hypotenuse facing the right angle of the right triangle may overlap a part of the magnetic detection unit 2.

Of protruding portions 57a and 57b of the bus bar 5 projecting from opposite sides of the case 3 in the X direction, the protruding portion 57b (on the X2 side) may include a bent portion 58. Among the three fixing portions 8, two fixing portions 8 may be provided in a region closer to the bent portion 58 than to the center 94 of the substrate 9 in the X direction.

With the above configuration, even when stress is applied in a direction in which the bus bar 5 is twisted or bent, for example, when the bus bar 5 is fastened to an external terminal or the like, and the stress is also applied to the case 3 via the bus bar 5, the substrate 9 can be stably fixed to the case 3. In other words, since two fixing portions 8 are provided in a region near the protruding portion 57b of the bus bar 5 having the bent portion 58, when a portion of the case 3 near the bent portion 58 is deformed during fastening of the bus bar 5, a force caused by the deformation can be dispersed. Accordingly, even when the bus bar 5 has the bent portion 58, the substrate 9 can be stably fixed to the case 3.

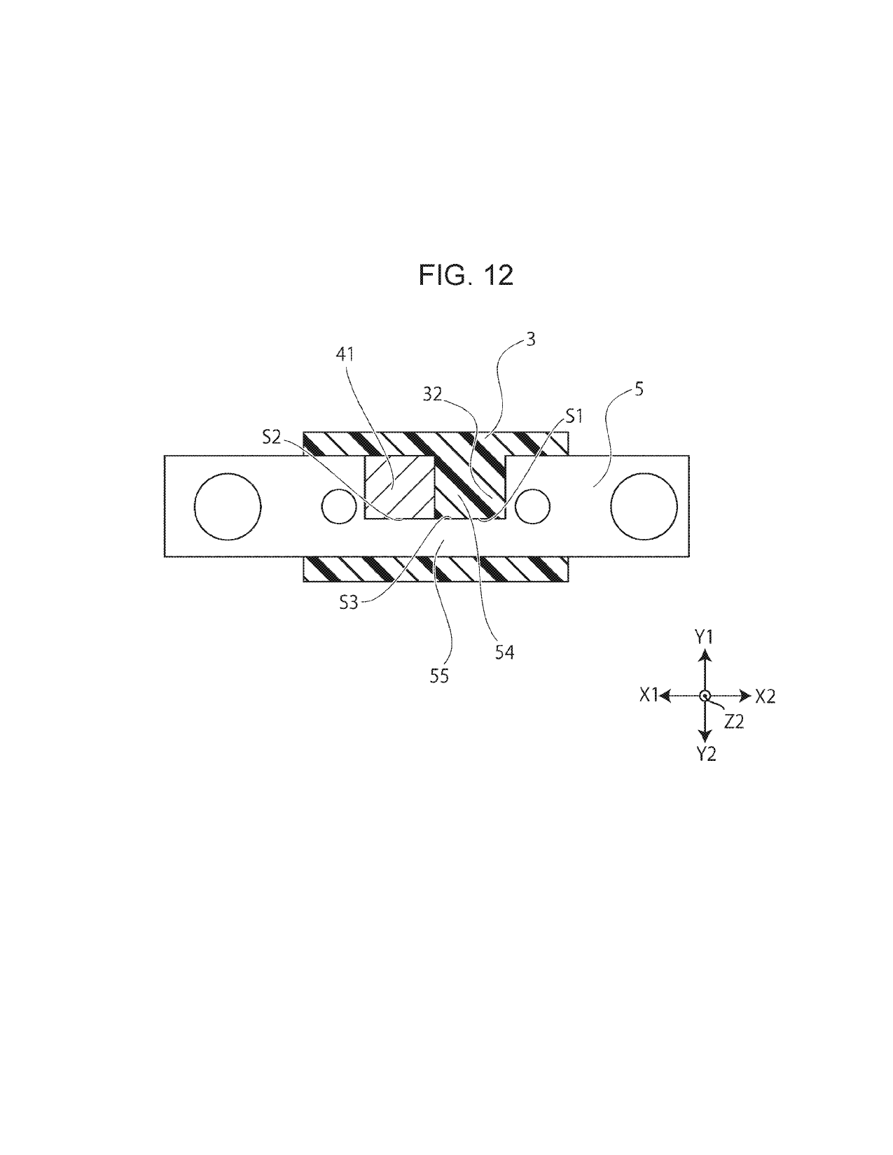

FIG. 12 is a partial cross-sectional view of the current sensor 1 in another modification different from that of FIG. 11, taken at a position corresponding to line XII-XII in FIG. 1, in which a vicinity of a surface of the bus bar 5 is cut along the X-Y plane. As illustrated in FIG. 12, a bus bar 5 in which the cutout portion 54 is provided only on one side of the constricted portion 55 may be used. In this case, as illustrated in FIG. 12, one guide portion 32 having the first reference surface S1 and one pillar portion 41 having the second reference surface S2 may be provided. Also with this configuration, similarly to the configuration of the case 3 and the cover 4 illustrated in FIGS. 3 and 4, the case 3, the cover 4, and the bus bar 5 can be accurately positioned.

The bus bar 5 illustrated in FIG. 12, in which the cutout portion 54 is provided only on one side of the constricted portion 55, has a simple structure and is therefore advantageous over the bus bar 5 illustrated in FIGS. 3 and 4, in which the cutout portions 54 are provided on opposite sides of the constricted portion 55.

However, from the viewpoints of ease of assembly and size reduction, the bus bar 5 illustrated in FIGS. 3 and 4, in which the cutout portions 54 are provided on opposite sides of the constricted portion 55, may be preferable. In other words, when the bus bar 5 illustrated in FIG. 12 is merely disposed in the bus-bar groove 31, the bus bar 5 can easily move in the X direction, resulting in poor assembly workability. Furthermore, when the magnetic shield member 6 is disposed as in FIGS. 3 and 4, a part of the magnetic shield member 6 is located outside the bus bar 5 on the Y2 side, making it difficult to reduce the size in the Y direction.

In the above embodiments, a configuration in which the present invention is applied to a current sensor 1 including the bus bar 5 has been described. However, the present invention may also be applied to a current sensor 1 that does not include the bus bar 5, that is, a current sensor that includes the magnetic detection unit 2, the case 3, and the cover 4, and does not include the bus bar 5, in which the bus bar 5 is held between the case 3 and the cover 4. Also when the present invention is applied according to this configuration, positioning is performed such that the first reference surface S1 of the case 3 and the second reference surface S2 of the cover 4 are pressed against the third reference surface S3, which is the end face 53 of the bus bar 5 to be attached to the current sensor 1 in the width direction. This allows the case 3 and the cover 4 to be accurately positioned when the bus bar 5 is mounted.

The embodiments disclosed in this specification are illustrative in all respects and are not intended to limit the present invention. It is to be understood that the scope of the present invention is defined by the claims, not limited by the above-described embodiments, and is intended to include all modifications within the meaning and scope equivalent to the claims.

The present invention is useful as a current sensor configured to measure a target current flowing through devices, for example, in order to control a power system of a vehicle including various devices.

What is claimed is:

1. A current sensor comprising:
a magnetic detection unit;
a case;
a cover; and
a bus bar,
wherein the bus bar includes a plate-like portion extending, among an X direction, a Y direction, and a Z direction perpendicular to one another, in the X direction, having a normal direction in the Z direction, and having a facing surface facing the magnetic detection unit,
wherein the plate-like portion of the bus bar having the facing surface is clamped between the case and the cover from opposite sides in the Z direction,
wherein the case has a first reference surface, the cover has a second reference surface, and the bus bar has a third reference surface,
wherein the case, the cover, and the bus bar are positioned by pressing the first reference surface and the second reference surface against the third reference surface, and
wherein the third reference surface is an end face of the plate-like portion of the bus bar in the Y direction.

2. The current sensor according to claim 1,
wherein the bus bar includes a constricted portion having a cutout portion recessed in the Y direction, and
wherein the third reference surface is the one end face of the constricted portion in the Y direction.

3. The current sensor according to claim 2,
wherein the case includes a bus-bar groove in a surface facing the cover, the bus bar being placeable in the bus bar groove,
wherein the bus-bar groove includes a guide portion projecting in the Y direction as viewed along the Z direction, and
wherein the guide portion is inserted in the cutout portion and has the first reference surface at a portion facing the third reference surface.

4. The current sensor according to claim 3,
wherein the cover includes a pillar portion projecting in the Z direction from a surface facing the case,
wherein the guide portion and the pillar portion are inserted into and fitted in the cutout portion, and
wherein the pillar portion has the second reference surface at a portion facing the third reference surface.

5. The current sensor according to claim 4,
wherein a pair of guide portions are provided apart from each other in the X direction with a gap therebetween,
wherein the pillar portion is fitted in the gap, and
wherein the two guide portions forming a pair in the X direction and the pillar portion are fitted in the cutout portion.

6. The current sensor according to claim 5,
wherein the bus bar includes a pair of cutout portions on both sides of the plate-like portion in the Y direction, and
wherein the case includes a pair of guide portions in the X direction, the guide portions corresponding to the pair of cutout portions,
wherein the cover includes a pair of pillar portions corresponding to the pair of cutout portions, and
wherein the end face of the constricted portion in one of the one cutout portions is the third reference surface, the guide portions fitted in the one cutout portion each have the first reference surface, and the pillar portion fitted in a gap between the pair of guide portions in the X direction and fitted in the one cutout portion has the second reference surface.

7. The current sensor according to claim 6,
wherein the other end face of the constricted portion opposite to the one end face having the third reference surface is a pressing surface, and
wherein the guide portions facing the pressing surface each have a first protrusion projecting in the Y direction in a surface facing the pressing surface,
wherein the pillar portion has a second protrusion projecting in the Y direction in a surface facing the pressing surface, and
wherein the first protrusion and the second protrusion press against the pressing surface.

8. The current sensor according to claim 3,
wherein the cutout portion has X-facing surfaces facing each other in the X direction,
wherein, of a pair of guide portions arranged in the X direction,
one guide portion has a third protrusion projecting in the X direction on a surface facing one of the X-facing surfaces,
wherein a surface of the other of the guide portions facing the other of the X-facing surfaces and the other of the X-facing surfaces of the cutout portion are in contact with each other, and
wherein the third protrusion presses against the other of the X-facing surfaces.

9. The current sensor according to claim 4, further comprising:
a U-shaped magnetic shield member,
wherein the magnetic shield member is insert-molded in the cover, and both end portions thereof project from a surface of the cover facing the bus bar,
wherein a pair of pillar portions are each disposed between the end portions of the magnetic shield member so as to be in contact with the magnetic shield member, and
wherein, as viewed from the case side toward the cover along the Z axis, the magnetic detection unit is disposed between the end portions of the magnetic shield member.

10. The current sensor according to claim 9, wherein the case has shield holes into which the end portions of the magnetic shield member are insertable without coming into contact the guide portions.

11. The current sensor according to claim 9,
wherein a dimension of the magnetic shield member in the Y direction is smaller than a dimension of the bus bar in the Y direction, and
wherein the magnetic shield member is disposed so as not to extend beyond the bus bar in the Y direction.

12. The current sensor according to claim 2,
wherein the current sensor 1 includes a pair of holding members configured to integrally hold the case, the cover, and the bus bar,
wherein the bus bar includes a pair of through-holes through which the holding members are insertable, and
wherein the pair of through-holes are respectively disposed on opposite sides of the constricted portion in the X direction with the constricted portion interposed therebetween.

13. The current sensor according to claim 12,
wherein the magnetic detection unit is mounted on a case-facing surface of a substrate,
wherein the substrate is provided above a substrate-facing surface of the case opposite to a bus-bar-facing surface facing the bus bar,
wherein the substrate includes cutout portions,
wherein the case includes engaging portions projecting from the substrate-facing surface, and
wherein by engaging the cutout portions with the engaging portions, the substrate is positioned with respect to the case.

14. The current sensor according to claim 13,
wherein the holding members comprise screws and the cover includes second through-holes through which the screws are insertable,
wherein the case includes screw-hole bosses projecting in the Z direction from the substrate-facing surface,
wherein the substrate is positioned between the two screw-hole bosses in the X direction as viewed along the Z direction, and
wherein the substrate is provided closer to the substrate-facing surface of the case than to a straight line connecting distal end portions of the two screw-hole bosses as viewed along the Y direction.

15. The current sensor according to claim 14,
wherein the case includes a wall portion projecting from the substrate-facing surface in the Z direction so as to surround the periphery of the substrate, and
wherein the wall portion projects from the substrate-facing surface to at least a position corresponding to a surface of the substrate opposite to the case-facing surface.

16. The current sensor according to claim 12,
wherein the cover includes, on a bottom surface opposite to the bus-bar-facing surface facing the bus bar, a protruding portion and a bottom portion that is a region other than the protruding portion,
wherein a portion of the magnetic shield member is insert-molded within the protruding portion,
wherein the holding members comprise screws and second through-holes through which the screws are insertable are provided in the bottom portion of the bottom surface, and
wherein a height from the bottom portion to a distal end of the protruding portion in the Z direction is greater than a height from the bottom portion to screw heads of the screws inserted through the second through-holes.

17. The current sensor according to claim 16, wherein the cover includes partition wall portions projecting from the bottom portion in the Z direction and extending in the X direction.

18. The current sensor according to claim 17, wherein the partition wall portions are disposed on opposite sides of each of the second through-holes in the Y direction, and wherein a height of the partition wall portions from the bottom portion and a height of the protruding portion from the bottom portion of the bottom surface in the Z direction are equal to each other.

19. The current sensor according to claim 14, further comprising three fixing portions configured to fix the substrate to the case,
wherein, as viewed from the Z direction, a right triangle is formed by three straight lines connecting the fixing portions,
wherein an opposite side and an adjacent side of the right triangle intersecting at a right angle are each parallel to the X direction or the Y direction, and
wherein a hypotenuse facing the right angle of the right triangle overlaps a part of the magnetic detection unit.

20. The current sensor according to claim 14, further comprising three fixing portions configured to fix the substrate to the case,
wherein one of protruding portions of the bus bar projecting from opposite sides of the case includes a bent portion, and
wherein two of the three fixing portions are provided in a region closer to the bent portion than to a center of the substrate in the X direction.

21. A current sensor comprising:
a magnetic detection unit;
a case; and
a cover,
wherein the case has a first reference surface configured to perform positioning by being pressed against an end face of a bus bar in a width direction thereof, and
wherein the cover has a second reference surface configured to perform positioning by being pressed against the end face of the bus bar in the width direction thereof.
